(19) United States
(12) Patent Application Publication
(10) Pub. No.: US 2006/0178005 A1
(43) Pub. Date: Aug. 10, 2006

(54) Pattern formation method

(75) Inventors: Masayuki Endo, Osaka (JP); Masaru Sasago, Osaka (JP)

Correspondence Address: MCDERMOTT WILL & EMERY LLP, 600 13TH STREET, N.W., WASHINGTON, DC, 20005-3096, US

(73) Assignee: MATSUSHITA ELECTRIC INDUSTRIAL CO., LTD.

(21) Appl. No.: 11/289,679

(22) Filed: Nov. 30, 2005

(30) Foreign Application Priority Data
Feb. 4, 2005 (JP) 2005-028471

(51) Int. Cl. H01L 21/4763

(52) U.S. Cl. 438/637

(57) ABSTRACT

A resist film is first formed on a substrate. Subsequently, a first barrier film including a water-soluble solvent is formed on the resist film, and a second barrier film including an alcoholic solvent is formed on the first barrier film. Thereafter, with a liquid provided on the second barrier film, pattern exposure is carried out by selectively irradiating the resist film with exposing light through the first barrier film and the second barrier film. Then, after removing the first barrier film and the second barrier film, the resist film having been subjected to the pattern exposure is developed, so as to form a resist pattern made of the resist film.

### CROSS-REFERENCE TO RELATED APLICATIONS

This application claims priority under 35 U.S.C. §119 on Patent Application No. 2005-28471 filed in Japan on Feb. 4, 2005, the entire contents of which are hereby incorporated by reference.

### BACKGROUND OF THE INVENTION

The present invention relates to a pattern formation method for use in fabrication process or the like for semiconductor devices, and more particularly, it relates to a pattern formation method in which a barrier film is formed on a resist film in immersion lithography.

In accordance with the increased degree of integration of semiconductor integrated circuits and downsizing of semiconductor devices, there are increasing demands for further rapid development of lithography technique. Currently, pattern formation is carried out through photolithography using exposing light of a mercury lamp, KrF excimer laser, ArF excimer laser or the like, and use of F₂ laser lasing at a shorter wavelength of 157 nm is being examined. However, since there remain a large number of problems in exposure systems and resist materials, photolithography using exposing light of a shorter wavelength has not been put to practical use.

In these circumstances, immersion lithography has been recently proposed for realizing further refinement of patterns by using conventional exposing light (for example, see M. Switkes and M. Rothschild, “Immersion lithography at 157 nm”, J. Vac. Sci. Technol., Vol. B19, p. 2353 (2001)). In the immersion lithography, a region in an exposure system sandwiched between a projection lens and a resist film formed on a wafer is filled with a liquid having a refractive index n (whereas n>1) and therefore, the NA (numerical aperture) of the exposure system has a value n·NA. As a result, the resolution of the resist film can be improved.

Also, in order to increase the refractive index of a liquid provided on a resist film, use of an acidic solution as the immersion liquid has been proposed (see, for example, B. W. Smith, A. Bourov, Y. Fan, L. Zavyalova, N. Lafferty, F. Cropanese, “Approaching the numerical aperture of water-Immersion Lithography at 193 nm”, Proc. SPIE, Vol. 5377, p. 273 (2004)).

Now, a conventional pattern formation method employing the immersion lithography will be described with reference to FIGS. 5A through 5D, 6A and 6B.

First, a positive chemically amplified resist material having the following composition is prepared:

| | | |
|---|---|---|
| Base polymer: poly((norbornene-5-methylene-t- | 2 | g |
| butylcarboxylate) (50 mol %) - (maleic anhydride) | | |
| (50 mol %)) | | |
| Acid generator: triphenylsulfonium trifluoromethane sulfonate | 0.06 | g |
| Quencher: triethanolamine | 0.002 | g |
| Solvent: propylene glycol monomethyl ether acetate | 20 | g |

Next, as shown in FIG. 5A, the aforementioned chemically amplified resist material is applied on a substrate 1 so as to form a resist film 2 with a thickness of 0.35 μm.

Then, as shown in FIG. 5B, a barrier film 3 made of a barrier film material having the following composition is formed on the resist film 2 by, for example, spin coating:

| | |
|---|---|
| Base polymer: polyvinyl hexafluoroisopropyl alcohol | 1 g |
| Solvent: n-butyl alcohol | 20 g |

Next, as shown in FIG. 5C, the resultant barrier film 3 is annealed with a hot plate at a temperature of 110° C. for 60 seconds.

Then, as shown in FIG. 5D, with a liquid (water) 4 provided above the resist film 2, pattern exposure is carried out by irradiating the resist film 2 with exposing light 5 of ArF excimer laser of a wavelength of 193 nm having NA of 0.68 through a mask 6.

After the pattern exposure, as shown in FIG. 6A, the resist film 2 is baked with a hot plate at a temperature of 105° C. for 60 seconds, and thereafter, the barrier film 3 is removed and the resultant resist film is developed with a 2.38 wt% tetramethylammonium hydroxide developer. In this manner, a resist pattern 2a made of an unexposed portion of the resist film 2 and having a line width of 0.09 μm is formed as shown in FIG. 6B.

However, as shown in FIG. 6B, the resist pattern 2a obtained by the conventional pattern formation method is in a defective shape having what is called a T-top portion. Furthermore, residues 2b are produced.

### SUMMARY OF THE INVENTION

The present inventors have variously examined the reason why the resist pattern formed by the conventional immersion lithography is in a defective shape, resulting in finding the following: In the immersion lithography, the barrier film 3 is provided between the resist film 2 and the liquid 4 in order to prevent performance degradation of the resist film 2 otherwise caused through contact between the immersion liquid 4 and the resist film 2. However, in removing the barrier film 3 after the exposure, the solubility of the barrier film 3 is so insufficient that the pattern failure occurs.

When the resist pattern 2a in such a defective shape is used for etching a target film, the resultant pattern of the target film is also in a defective shape, which disadvantageously lowers the productivity and the yield in the fabrication process for semiconductor devices.

In consideration of the aforementioned conventional problem, an object of the invention, is forming a fine pattern in a good shape by improving the solubility (removability) of a barrier film provided on a resist film in the immersion lithography.

The present inventors have found, on the basis of the results of the aforementioned examination, that the efficiency for removing a barrier film after exposure can be improved when the barrier film formed on a resist film has a multilayered structure composed of a first barrier film including a water-soluble solvent and a second barrier film including an alcoholic solvent.

Since the first barrier film is water-soluble, ionic bond is easily caused between a polymer included in the first barrier film and an alkaline developer or an aqueous solution generally used for removing the barrier film. As a result, the solubility of the first barrier film is improved. In addition, since the first barrier film is water-soluble, the second barrier film formed on the first barrier film and including alcohol as a solvent can be easily removed through what is called a lift-off function.

Furthermore, when the refractive index of the first barrier film is set to be higher than that of an immersion liquid, the efficiency for allowing exposing light to enter a resist film through the liquid can be improved. The first barrier film preferably has a refractive index higher than that of water because thus reflection of the exposing light on the surface of the first barrier film can be suppressed. When the refractive index of the first barrier film is, for example, 1.5 or more, incident light can be more smoothly introduced to the resist film.

The incident light is thus smoothly introduced for the following reason: When light having passed through a liquid enters a barrier film having a higher refractive index than the liquid, the incident angle of the incident light is smaller. As a result, scattering of the light can be suppressed.

The present invention was devised on the basis of the aforementioned findings and is specifically practiced as follows:

The first pattern formation method of this invention includes the steps of forming a resist film on a substrate; forming, on the resist film, a first barrier film including a water-soluble solvent; forming, on the first barrier film, a second barrier film including an alcoholic solvent; performing pattern exposure by selectively irradiating the resist film with exposing light through the first barrier film and the second barrier film with a liquid provided on the second barrier film; removing the first barrier film and the second barrier film; and forming a resist pattern made of the resist film by developing the resist film after the pattern exposure and after removing the first barrier film and the second barrier film.

The second pattern formation method of this invention includes the steps of forming a resist film on a substrate; forming, on the resist film, a first barrier film including a water-soluble solvent; forming, on the first barrier film, a second barrier film including an alcoholic solvent; performing pattern exposure by selectively irradiating the resist film with exposing light through the first barrier film and the second barrier film with a liquid provided on the second barrier film; and removing the first barrier film and the second barrier film and forming a resist pattern made of the resist film by developing the resist film after the pattern exposure.

In the first or second pattern formation method, since the second barrier film including the alcoholic solvent is insoluble in the immersion liquid, the first barrier film with a water-soluble property can be protected from the liquid such as water. In addition, in the first barrier film directly formed on the resist film, a polymer included therein is easily bonded through ionic bond with an alkaline aqueous solution or the like used for removing the barrier films, and therefore, the solubility of the first barrier film is improved. Moreover, the second barrier film can be easily removed through a lift-off function of the first barrier film. Since the first barrier film and the second barrier film are thus sufficiently removed, the resist pattern made of the resist film can be formed in a good shape.

In the first or second pattern formation method, the first barrier film preferably has a higher refractive index than the liquid. Thus, incident light (exposing light) can be more smoothly introduced to the resist film.

In the first or second pattern formation method, the first barrier film may include a polymer having a carboxylic acid group or a sulfonic acid group, such as polyacrylic acid, polyvinyl sulfonic acid, polyvinyl pyrrolidone, polystyrene sulfonic acid or pullulan.

Furthermore, the first barrier film may further include a compound for improving the refractive index such as a surface active agent (for example, an ionic surface active agent or a nonionic surface active agent).

As a water-soluble film having a lower refractive index than water with a refractive index of 1.44, a film made of a base polymer including a fluorine-based additive is conventionally used. Such a water-soluble film having a lower refractive index than water is disclosed in Japanese Laid-Open Patent Publication No. 2000-506287 (hereinafter referred to as Document 1). The technique described in Document 1 is not the immersion lithography but dry lithography, and its object is reflection inhibition for preventing exposing light having passed through a resist film and reflected on the surface of a target film from being reflected again on the inner top face of the resist film and prevention of multiple interference caused by the re-reflection. Accordingly, what is called an anti-reflection film disclosed in Document 1 is not derived from the technical idea of this invention related to the solubility of a barrier film itself and the increase of the refractive index beyond that of water.

In the first or second pattern formation method, the water-soluble solvent of the first barrier film can be water, an acidic solution or an alkaline aqueous solution.

In this case, the acidic solution can be a hydrochloric acid aqueous solution or an acetic acid aqueous solution.

Also, the alkaline aqueous solution can be a tetramethylammonium hydroxide aqueous solution, a tetraethylammonium hydroxide aqueous solution, a tetra n-butylammonium hydroxide aqueous solution, a tetra t-butylammonium hydroxide aqueous solution or a choline aqueous solution.

In the first or second pattern formation method, the alcoholic solvent of the second barrier film can be ethanol, isopropyl alcohol, n-propyl alcohol, t-butyl alcohol, sec-butyl alcohol or n-butyl alcohol.

In the first or second pattern formation method, the second barrier film may include a polymer having a hydroxy group, such as polyvinyl alcohol or polyvinyl hexafluoroisopropyl alcohol.

According to the invention, the first and second barrier films may be removed before the development as in the first pattern formation method or may be removed during the development as in the second pattern formation method. Both methods have their advantages as follows: When the barrier films are removed before the development as in the first pattern formation method, the development of the resist film can be smoothly performed without fail. Alternatively, when the barrier films are removed during the development of the resist film as in the second pattern formation method, the dissolution characteristic of the resist film can be advantageously controlled to be improved. Specifically, when the barrier films are removed simultaneously with the development, the dissolution characteristic of the resist film can be controlled to given extent.

Now, the dissolution characteristic of a resist film will be described with reference to FIG. 7. In general, when the dissolution characteristic of a resist film is high, the dissolution rate is abruptly increased when exposure exceeds a given threshold value (a threshold region of FIG. 7) (as shown with a graph A of a broken line in FIG. 7). As the change of the dissolution rate against the exposure is more abrupt, a difference in the solubility between an exposed portion and an unexposed portion of the resist film is larger, and hence, the resist pattern can be more easily formed in a good shape. Accordingly, in the case where the barrier films are removed during the development, the dissolution rate is wholly lowered correspondingly to the removal of the barrier films, and hence, the change in a portion surrounded with a circle C in FIG. 7 can be reduced to be flatter. As a result, in the case where the actual resist film has the dissolution characteristic as shown with a graph B, the dissolution rate attained with smaller exposure can be adjusted to be comparatively constant at a low dissolution rate even when the small exposure varies to some extent. Accordingly, a difference in the solubility between an exposed portion and an unexposed portion of the resist film can be easily caused, resulting in easily forming a resist pattern in a good shape.

In the first pattern formation method, an aqueous solution used for removing the first or second barrier film may be an aqueous solution having hydrogen ion concentration exponent (pH) sufficient for dissolving the first or second barrier film. For example, a developer or a diluted developer may be used. With respect to the degree of dilution of the diluted developer, the concentration is lower than that of a general developer, i.e., a 2.38 wt% tetramethylammonium hydroxide aqueous solution, and is preferably, for example, not less than 0.001% and not more than 2%, which does not limit the invention.

The first or second pattern formation method preferably further includes, before the step of forming a second barrier film, a step of performing first annealing on the first barrier film.

Similarly, the first or second pattern formation method preferably further includes, before the step of performing pattern exposure, a step of performing second annealing on the second barrier film.

When each barrier film is annealed in this manner, the denseness of the barrier film is improved, so that the insolubility thereof in the liquid provided thereon in the exposure can be increased. However, when the denseness of the barrier film is increased too much, it becomes difficult to dissolve the barrier film for removal, and therefore, it is preferably annealed at a temperature in an appropriate range. For example, the temperature is preferably not less than 100° C. and not more than 150° C., which does not limit the invention.

In the first or pattern formation method, the immersion liquid can be water or an acidic solution.

In this case, the acidic solution can be a cesium sulfonate (Cs₂SO₄) aqueous solution or a phosphoric acid (H₃PO₄) aqueous solution. Thus, the refractive index of the liquid can be increased. Furthermore, the liquid may include an additive such as a surface active agent.

In the first or second pattern formation method, the exposing light can be KrF excimer laser, Xe₂ laser, ArF excimer laser, F₂ laser, KrAr laser or Ar₂ laser.

### BRIEF DESCRIPTION OF THE DRAWINGS

FIGS. 1A, 1B, 1C and 1D are cross-sectional views for showing procedures in a pattern formation method according to Embodiment 1 of the invention;

FIGS. 2A, 2B, 2C and 2D are cross-sectional views for showing other procedures in the pattern formation method of Embodiment 1;

FIGS. 3A, 3B, 3C and 3D are cross-sectional views for showing procedures in a pattern formation method according to Embodiment 2 of the invention;

FIGS. 4A, 4B, 4C and 4D are cross-sectional views for showing other procedures in the pattern formation method of Embodiment 2;

FIGS. 5A, 5B, 5C and 5D are cross-sectional views for showing procedures in a conventional pattern formation method employing immersion lithography;

FIGS. 6A and 6B are cross-sectional views for showing other procedures in the conventional pattern formation method employing immersion lithography; and

FIG. 7 is a graph for explaining control of solubility of a resist in the pattern formation method of this invention.

### DETAILED DESCRIPTION OF THE INVENTION

### Embodiment 1

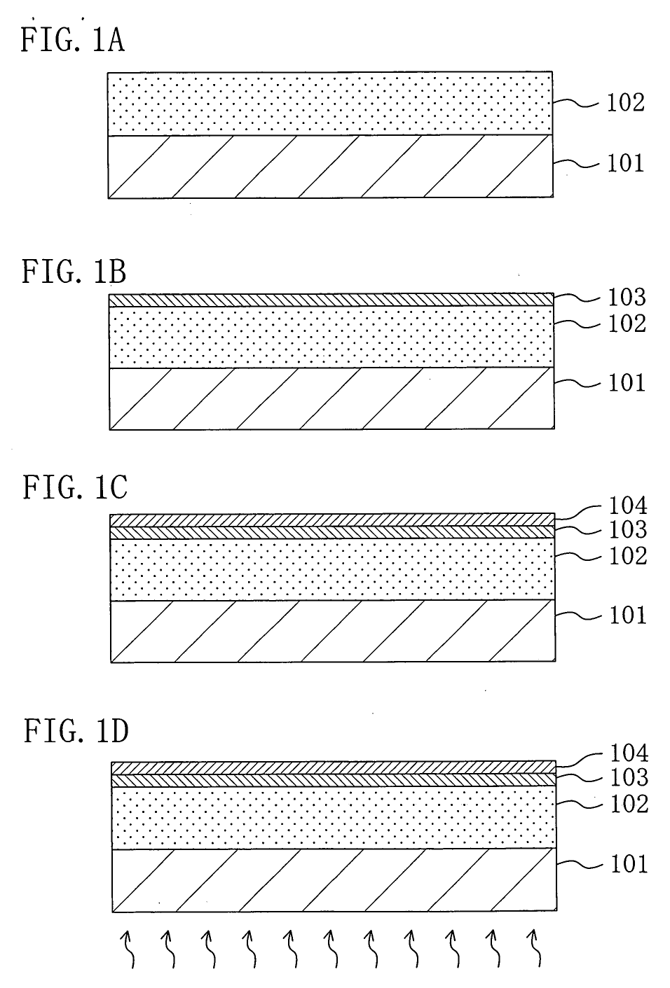

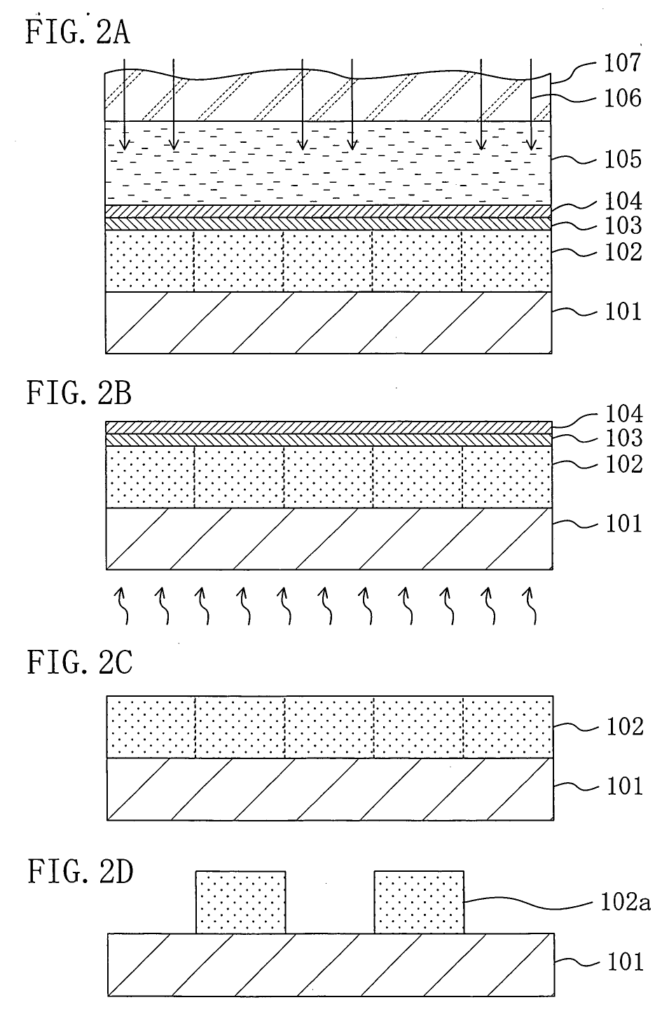

A pattern formation method according to Embodiment 1 of the invention will now be described with reference to FIGS. 1A through 1D and 2A through 2D.

First, a positive chemically amplified resist material having the following composition is prepared:

| | | |
|---|---|---|
| Base polymer: poly((norbornene-5-methylene-t- | 2 | g |
| butylcarboxylate) (50 mol %) - (maleic anhydride) | | |
| (50 mol %)) | | |
| Acid generator: triphenylsulfonium trifluoromethane sulfonate | 0.06 | g |
| Quencher: triethanolamine | 0.002 | g |
| Solvent: propylene glycol monomethyl ether acetate | 20 | g |

Next, as shown in FIG. 1A, the aforementioned chemically amplified resist material is applied on a substrate 101 so as to form a resist film 102 with a thickness of 0.35 μm.

Then, as shown in FIG. 1B, by using a first barrier film material having the following composition, a first barrier film 103 having a thickness of 50 nm is formed on the resist film 102 by, for example, spin coating:

| | |
|---|---|
| Base polymer: polyacrylic acid | 1 g |
| Solvent: water | 20 g |

Next, as shown in FIG. 1C, by using a second barrier film material having the following composition, a second barrier film 104 having a thickness of 60 nm is formed on the first barrier film 103 by, for example, the spin coating:

| | |
|---|---|
| Base polymer: polyvinyl hexafluoroisopropyl alcohol | 1 g |
| Solvent: n-butyl alcohol | 20 g |

Then, as shown in FIG. 1D, the first barrier film 103 and the second barrier film 104 thus formed are annealed with a hot plate at a temperature of 110° C. for 60 seconds, so as to improve the denseness of the first barrier film 103 and the second barrier film 104.

Next, as shown in FIG. 2A, with a liquid 105 of water provided between the second barrier film 104 and a projection lens 107 by, for example, a puddle method, pattern exposure is carried out by irradiating the resist film 102 through the second barrier film 104 and the first barrier film 103 with exposing light 106 of ArF excimer laser with NA of 0.68 having passed through a mask (not shown).

After the pattern exposure, as shown in FIG. 2B, the resist film 102 is baked with a hot plate at a temperature of 105° C. for 60 seconds (post exposure bake).

Next, as shown in FIG. 2C, the second barrier film 104 and the first barrier film 103 are removed with, for example, a 0.005 wt% tetramethylammonium hydroxide aqueous solution (diluted alkaline developer). Thereafter, the resultant resist film 102 is developed with a 2.38 wt% tetramethylammonium hydroxide developer. Thus, a resist pattern 102a made of an unexposed portion of the resist film 102 and having a line width of 0.09 μm is formed in a good shape as shown in FIG. 2D.

In this manner, according to Embodiment 1, the first barrier film 103 including polyacrylic acid and using water as a solvent is formed in the procedure shown in FIG. 1B, and thereafter, the second barrier film 104 including polyvinyl hexafluoroisopropyl alcohol and using alcohol as a solvent is formed on the first barrier film 103 in the procedure shown in FIG. 1C. Therefore, in the first barrier film 103, the base polymer is easily bonded through ionic bond with the alkaline aqueous solution used for removing the barrier films, and thus, the solubility of the first barrier film 103 is improved. Furthermore, the second barrier film 104 can be easily removed owing to a lift-off function of the first barrier film 103. Accordingly, in the procedure for removing the barrier films shown in FIG. 2C, the first barrier film 103 and the second barrier film 104 can be sufficiently removed, resulting in forming the resist pattern 102a in a good shape without producing residues.

Although the tetramethylammonium hydroxide aqueous solution is used as the alkaline aqueous solution for removing the first barrier film 103 and the second barrier film 104 in Embodiment 1, a tetraethylammonium hydroxide aqueous solution, a tetra n-butylammonium hydroxide aqueous solution, a tetra t-butylammonium hydroxide aqueous solution or a choline aqueous solution may be used instead.

### Embodiment 2

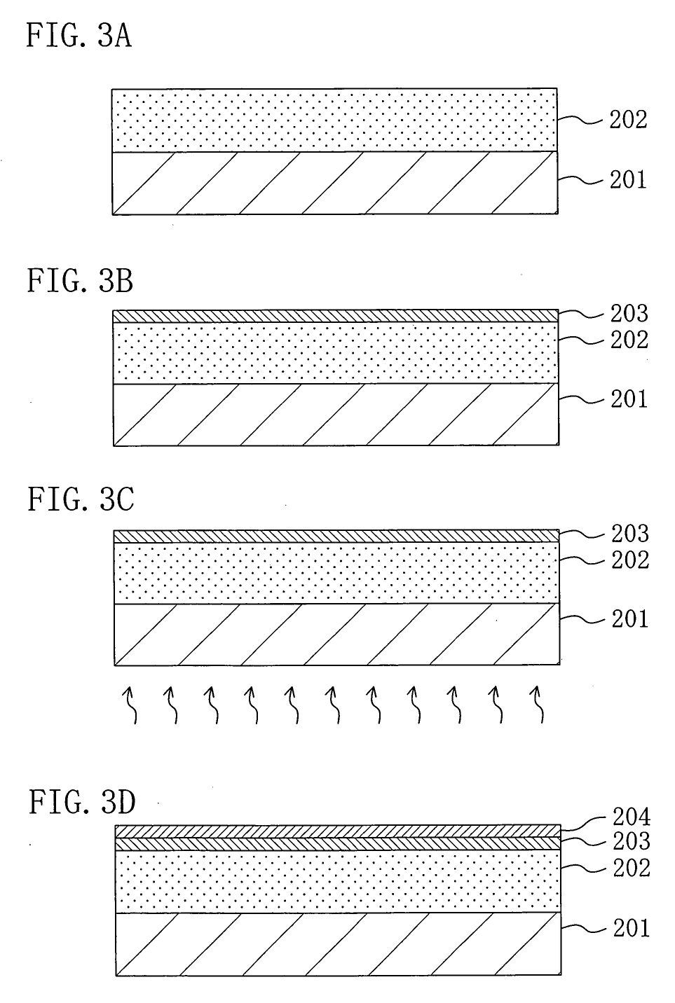

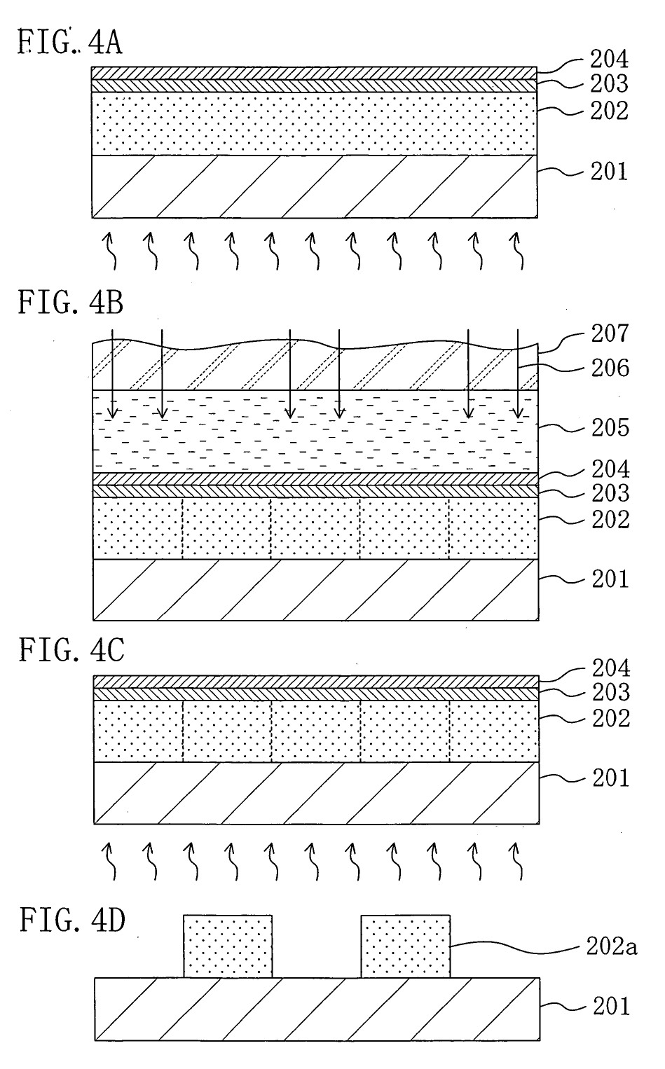

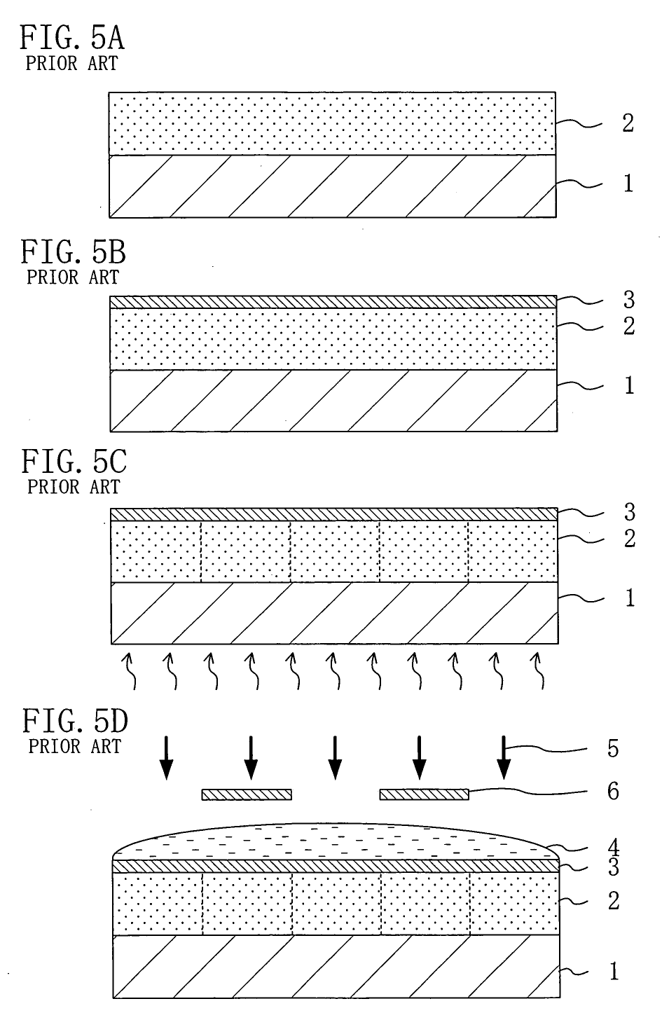

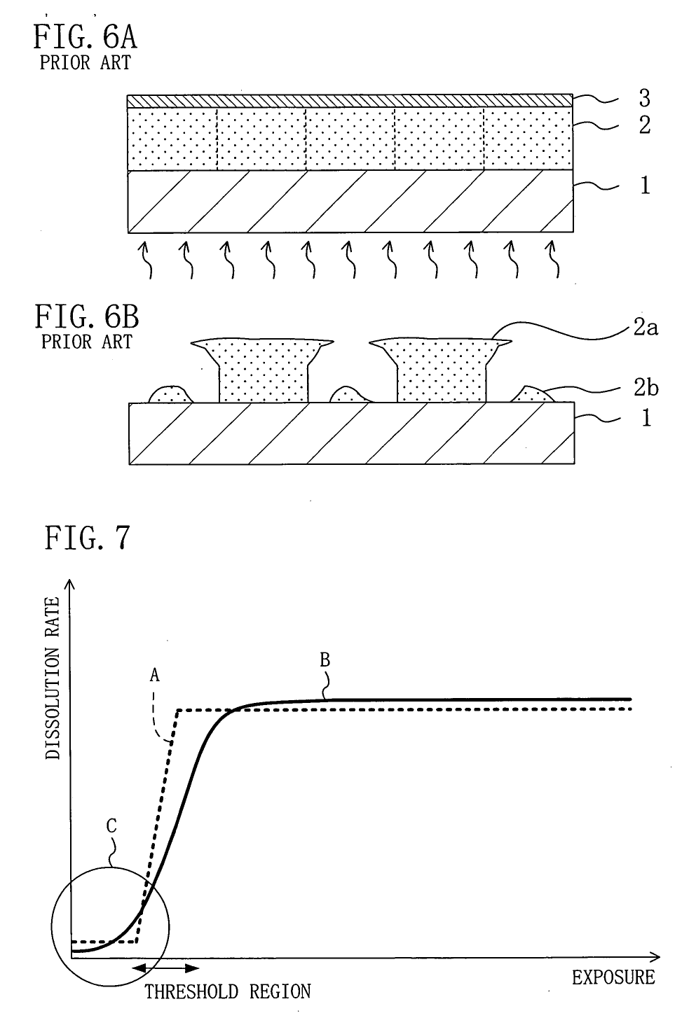

A pattern formation method according to Embodiment 2 of the invention will now be described with reference to FIGS. 3A through 3D and 4A through 4D.

First, a positive chemically amplified resist material having the following composition is prepared:

| | | |
|---|---|---|
| Base polymer: poly((norbornene-5-methylene-t- | 2 | g |
| butylcarboxylate) (50 mol %) - (maleic anhydride) | | |
| (50 mol %)) | | |
| Acid generator: triphenylsulfonium trifluoromethane sulfonate | 0.06 | g |
| Quencher: triethanolamine | 0.002 | g |
| Solvent: propylene glycol monomethyl ether acetate | 20 | g |

Next, as shown in FIG. 3A, the aforementioned chemically amplified resist material is applied on a substrate 201 so as to form a resist film 202 with a thickness of 0.35 μm.

Then, as shown in FIG. 3B, by using a first barrier film material having the following composition, a first barrier film 203 having a thickness of 70 nm is formed on the resist film 202 by, for example, the spin coating:

| | |
|---|---|
| Base polymer: polyvinyl pyrrolidone | 1 g |
| Solvent: 0.05 wt % hydrochloric acid aqueous solution | 20 g |

Next, as shown in FIG. 3C, the first barrier film 203 thus formed is annealed with a hot plate at a temperature of 100° C. for 60 seconds, so as to improve the denseness of the first barrier film 203.

Next, as shown in FIG. 3D, by using a second barrier film material having the following composition, a second barrier film 204 having a thickness of 30 nm is formed on the first barrier film 203 by, for example, the spin coating:

| | |
|---|---|
| Base polymer: polyvinyl hexafluoroisopropyl alcohol | 1 g |
| Solvent: t-butyl alcohol | 20 g |

Then, as shown in FIG. 4A, the second barrier film 204 thus formed is annealed with a hot plate at a temperature of 110° C. for 60 seconds, so as to improve the denseness of the second barrier film 204.

Next, as shown in FIG. 4B, with a liquid 205 of water provided between the second barrier film 204 and a projection lens 207 by, for example, the puddle method, pattern exposure is carried out by irradiating the resist film 202 through the second barrier film 204 and the first barrier film 203 with exposing light 206 of ArF excimer laser with NA of 0.68 having passed through a mask (not shown).

After the pattern exposure, as shown in FIG. 4C, the resist film 202 is baked with a hot plate at a temperature of 105° C. for 60 seconds (post exposure bake).

Next, the second barrier film 204 and the first barrier film 203 are removed and the baked resist film 202 is developed with, for example, a 2.38 wt% tetramethylammonium hydroxide developer. Thus, a resist pattern 202a made of an unexposed portion of the resist film 202 and having a line width of 0.09 μm is formed in a good shape as shown in FIG. 4D.

In this manner, according to Embodiment 2, the first barrier film 203 including polyvinyl pyrrolidone and using hydrochloric acid as a solvent is formed in the procedure shown in FIG. 3B, and thereafter, the second barrier film 204 including polyvinyl hexafluoroisopropyl alcohol and using alcohol as a solvent is formed on the annealed first barrier film 203 in the procedure shown in FIG. 3D. Therefore, in the first barrier film 203, the base polymer is easily bonded through ionic bond with the alkaline aqueous solution used for removing the barrier films, and thus, the solubility of the first barrier film 203 is improved. Furthermore, the second barrier film 204 can be easily removed owing to the lift-off function of the first barrier film 203. Accordingly, in the development procedure shown in FIG. 4D, the first barrier film 203 and the second barrier film 204 can be sufficiently removed, resulting in forming the resist pattern 202a in a good shape without producing residues.

Although water is used as the solvent of the first barrier film 103 in Embodiment 1 and a hydrochloric acid aqueous solution is used as the solvent of the first barrier film 203 in Embodiment 2, an acetic acid aqueous solution may be used as the solvent of the first barrier film. Alternatively, as the solvent of the first barrier film 103 or 203, an alkaline aqueous solution such as a tetramethylammonium hydroxide aqueous solution, a tetraethylammonium hydroxide aqueous solution, a tetra n-butylammonium hydroxide aqueous solution, a tetra t-butylammonium hydroxide aqueous solution or a choline aqueous solution may be used.

In some cases, the thickness of each of the first barrier film and the second barrier film is preferably approximately 30 nm through 70 nm as in Embodiments 1 and 2. However, the thickness of the barrier film is not limited to this, and the lower limit of the thicknesses is a thickness sufficient for preventing a component of the resist film from eluting into the liquid or preventing the liquid from permeating into the resist film, and the upper limit is a thickness not preventing the transmission of the exposing light and easily removed. For example, the thicknesses is not less than approximately 10 nm and not more than approximately 100 nm depending upon the composition of the barrier film.

Furthermore, the first barrier film 103 and the second barrier film 104 are simultaneously annealed after forming the second barrier film 104 in Embodiment 1, and each of the first and second barrier films 203 and 204 is annealed after its formation in Embodiment 2. Such annealing of the barrier films is not always necessary and is appropriately performed in accordance with the composition, the thickness and the like of the barrier film to be formed.

Although water is used as the immersion liquid in each embodiment, an aqueous solution of cesium sulfate (Cs₂SO₄) or phosphoric acid (H₃PO₄) may be used instead for improving the refractive index of the immersion liquid. Furthermore, a surface active agent may be added to the immersion liquid.

Although the exposing light is ArF excimer laser in each embodiment, the exposing light is not limited to it but may be KrF excimer laser, Xe₂ laser, F₂ laser, KrAr laser or Ar₂ laser instead.

Furthermore, the puddle method is employed for providing the liquid onto the second barrier film in each embodiment, which does not limit the invention, and for example, a dip method in which the whole substrate is dipped in the liquid may be employed instead.

Moreover, although a positive chemically amplified resist is used for forming the resist film in each embodiment, the present invention is applicable also to a negative chemically amplified resist. Also, the invention is applicable not only to a chemically amplified resist but also to a general resist.

As described so far, according to the pattern formation method of this invention, a barrier film formed on a resist film can be sufficiently removed, so that a resist pattern can be formed in a good shape. Accordingly, the present invention is useful as a method for forming a fine pattern to be employed in fabrication process or the like for semiconductor devices.

What is claimed is:

1. A pattern formation method comprising the steps of:
forming a resist film on a substrate;
forming, on said resist film, a first barrier film including a water-soluble solvent;
forming, on said first barrier film, a second barrier film including an alcoholic solvent;
performing pattern exposure by selectively irradiating said resist film with exposing light through said first barrier film and said second barrier film with a liquid provided on said second barrier film;
removing said first barrier film and said second barrier film; and
forming a resist pattern made of said resist film by developing said resist film after the pattern exposure and after removing said first barrier film and said second barrier film.

2. The pattern formation method of claim 1,
wherein said first barrier film has a higher refractive index than said liquid.

3. The pattern formation method of claim 1, further comprising, before the step of forming a second barrier film, a step of performing first annealing on said first barrier film.

4. The pattern formation method of claim 1, further comprising, before the step of performing pattern exposure, a step of performing second annealing on said second barrier film.

5. The pattern formation method of claim 1,
wherein said water-soluble solvent of said first barrier film is water, an acidic solution or an alkaline aqueous solution.

6. The pattern formation method of claim 5,
wherein said acidic solution is a hydrochloric acid aqueous solution or an acetic acid aqueous solution.

7. The pattern formation method of claim 5,
wherein said alkaline aqueous solution is a tetramethylammonium hydroxide aqueous solution, a tetraethylammonium hydroxide aqueous solution, a tetra n-butylammonium hydroxide aqueous solution, a tetra t-butylammonium hydroxide aqueous solution or a choline aqueous solution.

8. The pattern formation method of claim 1,
wherein said first barrier film includes a polymer having a carboxylic acid group or a sulfonic acid group.

9. The pattern formation method of claim 1,
wherein said alcoholic solvent of said second barrier film is ethanol, isopropyl alcohol, n-propyl alcohol, t-butyl alcohol, sec-butyl alcohol or n-butyl alcohol.

10. The pattern formation method of claim 1,
wherein said second barrier film includes a polymer having a hydroxy group.

11. The pattern formation method of claim 1,
wherein said liquid is water or an acidic solution.

12. The pattern formation method of claim 11,
wherein said acidic solution is a cesium sulfonate aqueous solution or a phosphoric acid aqueous solution.

13. The pattern formation method of claim 1,
wherein said exposing light is KrF excimer laser, Xe₂ laser, ArF excimer laser, F₂ laser, KrAr laser or Ar₂ laser.

14. A pattern formation method comprising the steps of:
forming a resist film on a substrate;
forming, on said resist film, a first barrier film including a water-soluble solvent;
forming, on said first barrier film, a second barrier film including an alcoholic solvent;
performing pattern exposure by selectively irradiating said resist film with exposing light through said first barrier film and said second barrier film with a liquid provided on said second barrier film; and
removing said first barrier film and said second barrier film and forming a resist pattern made of said resist film by developing said resist film after the pattern exposure.

15. The pattern formation method of claim 14,
wherein said first barrier film has a higher refractive index than said liquid.

16. The pattern formation method of claim 14, further comprising, before the step of forming a second barrier film, a step of performing first annealing on said first barrier film.

17. The pattern formation method of claim 14, further comprising, before the step of performing pattern exposure, a step of performing second annealing on said second barrier film.

18. The pattern formation method of claim 14,
wherein said water-soluble solvent of said first barrier film is water, an acidic solution or an alkaline aqueous solution.

19. The pattern formation method of claim 18,
wherein said acidic solution is a hydrochloric acid aqueous solution or an acetic acid aqueous solution.

20. The pattern formation method of claim 18,
wherein said alkaline aqueous solution is a tetramethylammonium hydroxide aqueous solution, a tetraethylammonium hydroxide aqueous solution, a tetra n-butylammonium hydroxide aqueous solution, a tetra t-butylammonium hydroxide aqueous solution or a choline aqueous solution.

21. The pattern formation method of claim 14,
wherein said first barrier film includes a polymer having a carboxylic acid group or a sulfonic acid group.

22. The pattern formation method of claim 14,
wherein said alcoholic solvent of said second barrier film is ethanol, isopropyl alcohol, n-propyl alcohol, t-butyl alcohol, sec-butyl alcohol or n-butyl alcohol.

23. The pattern formation method of claim 14,
wherein said second barrier film includes a polymer having a hydroxy group.

24. The pattern formation method of claim 14,
wherein said liquid is water or an acidic solution.

25. The pattern formation method of claim 24,
wherein said acidic solution is a cesium sulfonate aqueous solution or a phosphoric acid aqueous solution.

26. The pattern formation method of claim 14,
wherein said exposing light is KrF excimer laser, Xe₂ laser, ArF excimer laser, F₂ laser, KrAr laser or Ar₂ laser.
